(19) United States
(12) Patent Application Publication
(10) Pub. No.: US 2025/0309217 A1
(43) Pub. Date: Oct. 2, 2025

(54) ELECTRONIC DEVICE

(71) Applicant: Merry Electronics(Shenzhen) Co., Ltd., ShenZhen (CN)

(72) Inventors: Yung-Hsiang Chang, Taichung (TW); Jia Yin Wu, Taichung (TW)

(73) Assignee: Merry Electronics(Shenzhen) Co., Ltd., ShenZhen (CN)

(21) Appl. No.: 19/212,573

(22) Filed: May 19, 2025

Related U.S. Application Data
(63) Continuation-in-part of application No. 18/646,772, filed on Apr. 26, 2024.

(30) Foreign Application Priority Data
Mar. 28, 2024 (TW) 113111865

(51) Int. Cl. H01L 25/18; H01L 23/00; H01L 23/053; H01L 23/13; H01L 23/498; H01L 23/538

(52) U.S. Cl. CPC H01L 25/18; H01L 23/13; H01L 23/49838; H01L 23/5385; H01L 23/053; H01L 24/32; H01L 24/48; H01L 24/73; H01L 2224/32225; H01L 2224/48137; H01L 2224/48225; H01L 2224/48229; H01L 2224/73265; H01L 2924/35

(57) ABSTRACT

Provided is an electronic device, which includes a first substrate, a package, a first sensing chip, a first processing chip, a second processing chip and a first adhesive. The package is disposed on a first surface of the first substrate and defines a first chamber with the first substrate. One of the first substrate and the package has a second chamber. The second chamber has a first opening end and a first bottom wall opposite to each other. The first opening end is facing a direction away from the first chamber. The first bottom wall is located between the first opening end and the first chamber. The first sensing chip is located in the first chamber, and electrically connected to the first processing chip. The second processing chip is disposed in the second chamber, and air isolated from the first chamber.

### CROSS-REFERENCE TO RELATED APPLICATION

This application is a continuation-in-part application of and claims the priority benefit of U.S. application Ser. No. 18/646,772, filed on Apr. 26, 2024, which claims the priority benefit of Taiwan application serial no. 113111865, filed on Mar. 28, 2024. The entirety of each of the above-mentioned patent applications is hereby incorporated by reference herein and made a part of this specification.

### BACKGROUND

### Technical Field

The disclosure relates to an electronic device.

### Related Art

In electronic devices, multiple sensors are often integrated within a same package structure. However, in addition to the difficulty in miniaturizing the package structure, the foregoing method may also generate mutual interference (such as signal interference or thermal effects) by disposing chips with different functions within a same chamber, thereby reducing the sensing performance of the electronic device.

### SUMMARY

The disclosure provides an electronic device, which can dispose a sensing chip and a processing chip in different chambers in order to reduce the interference generated by the processing chip on the sensing chip during operation, and can have better sensing performance.

The electronic device of the disclosure includes a first substrate, a package, a first sensing chip, a first processing chip, a second processing chip, and a first adhesive. The first substrate has a first surface and a second surface opposite to each other, and a via penetrating through the first substrate and connected to the first surface and the second surface. The package is disposed on the first surface of the first substrate and defines a first chamber with the first substrate. One of the first substrate and the package has a second chamber. The second chamber has a first opening end and a first bottom wall opposite to each other. The first opening end is facing a direction away from the first chamber. The first bottom wall is located between the first opening end and the first chamber. The first sensing chip is disposed on the first surface of the first substrate, and is located in the first chamber and covers the via. The first sensing chip is electrically connected to the first processing chip. The second processing chip is disposed in the second chamber. The second processing chip is air isolated from the first chamber. The first adhesive is filled in the second chamber and at least clads the second processing chip.

In an embodiment of the disclosure, the first substrate has the second chamber extending from the second surface toward the first surface.

In an embodiment of the disclosure, the first processing chip is disposed in the second chamber of the first substrate, adjoining the second processing chip, and the first adhesive further clads the first processing chip.

In an embodiment of the disclosure, the first adhesive has a top surface away from the first bottom wall of the second chamber, and the top surface is aligned with or is not beyond the second surface of the first substrate.

In an embodiment of the disclosure, the electronic device further includes a metal plate, which is disposed on the top surface of the first adhesive, and covers the second chamber and electrically connected to the first substrate. The metal plate has an opening. The opening exposes a portion of the top surface of the first adhesive.

In an embodiment of the disclosure, the metal plate extends to cover the second surface of the first substrate. There is an air gap between the metal plate and the first adhesive.

In an embodiment of the disclosure, a surface of the metal plate relatively away from the top surface of the first adhesive is aligned with or is not beyond the second surface of the first substrate.

In an embodiment of the disclosure, the electronic device further includes a second sensing chip, which is disposed in the second chamber of the first substrate, adjoining the second processing chip, and the first adhesive further clads the second sensing chip.

In an embodiment of the disclosure, the electronic device further includes a second sensing chip, disposed on the first surface of the first substrate, and located in the first chamber. The second sensing chip is electrically connected to the second processing chip through the first substrate.

In an embodiment of the disclosure, the package includes a second substrate and a third substrate. The second substrate is disposed on the first surface of the first substrate, and has an opening penetrating through the second substrate. The third substrate is disposed on the second substrate, and has a third surface and a fourth surface opposite to each other and a second chamber extending from the third surface toward the fourth surface. The first surface of the first substrate, the opening of the second substrate, and the fourth surface of the third substrate define a space of the first chamber. The second substrate includes at least one conductive path. The first substrate is electrically connected to the third substrate by the at least one conductive path of the second substrate.

In an embodiment of the disclosure, the first processing chip is disposed in the second chamber of the third substrate, adjoining the second processing chip. The first adhesive further clads the first processing chip.

In an embodiment of the disclosure, the first adhesive has a top surface away from the first bottom wall of the second chamber. The top surface is aligned with or is not beyond the third surface of the third substrate.

In an embodiment of the disclosure, the electronic device further includes a metal plate, which is disposed on the top surface of the first adhesive, and extends to cover the second chamber and electrically connected to the third substrate. The metal plate has an opening. The opening exposes a portion of the top surface of the first adhesive.

In an embodiment of the disclosure, the metal plate extends to cover the third surface of the third substrate. There is an air gap between the metal plate and the first adhesive.

In an embodiment of the disclosure, the first substrate has a third chamber extending from the second surface toward the first surface. The third chamber has a second opening end and a second bottom wall opposite to each other. The second opening end is facing the direction away from the first chamber, and the second bottom wall is located between the second opening end and the first chamber. The first processing chip is disposed in the third chamber of the first substrate.

In an embodiment of the disclosure, the electronic device further includes a second sensing chip, which is disposed on the fourth surface of the third substrate, and located in the first chamber. The second sensing chip is electrically connected to the second processing chip through the third substrate.

In an embodiment of the disclosure, the electronic device further includes a second sensing chip, which is disposed in the second chamber of the third substrate, adjoining the second processing chip. The first adhesive further clads the second sensing chip.

In an embodiment of the disclosure, the electronic device further includes a second adhesive, which is filled in the third chamber of the first substrate, and at least clads the first processing chip.

In an embodiment of the disclosure, the electronic device further includes a metal plate, which is disposed on the top surface of the second adhesive, and electrically connected to the first substrate. The metal plate has an opening. The opening exposes a portion of the top surface of the second adhesive.

In an embodiment of the disclosure, the electronic device further includes multiple conductive members, which are disposed on the second surface of the first substrate, and electrically connected to the first processing chip and the second processing chip.

Based on the above, in the design of the electronic device of the disclosure, the package and the substrate define a first chamber. One of the first substrate and the package has a second chamber. The first sensing chip is located in the first chamber. The second processing chip is located in the second chamber and air isolated from the first chamber. By means of this design, the sensing chip and the processing chip may be respectively disposed in different chambers, which can reduce interference generated by the processing chip on the sensing chip during operation, thereby allowing the electronic device of the disclosure to have better sensing performance.

In order to make the features and advantages of the disclosure more comprehensible, the following embodiments are given and described in detail with the accompanying drawings as follows.

### BRIEF DESCRIPTION OF THE DRAWINGS

FIG. 1 is a schematic cross-sectional diagram of an electronic device according to an embodiment of the disclosure.

FIG. 2 is a schematic cross-sectional diagram of an electronic device according to another embodiment of the disclosure.

FIG. 3 is a schematic cross-sectional diagram of an electronic device according to another embodiment of the disclosure.

FIG. 4 is a schematic cross-sectional diagram of an electronic device according to another embodiment of the disclosure.

FIG. 5 is a schematic cross-sectional diagram of an electronic device according to another embodiment of the disclosure.

FIG. 6 is a schematic cross-sectional diagram of an electronic device according to another embodiment of the disclosure.

FIG. 7 is a schematic cross-sectional diagram of an electronic device according to another embodiment of the disclosure.

FIG. 8 is a schematic cross-sectional diagram of an electronic device according to another embodiment of the disclosure.

FIG. 9 is a schematic cross-sectional diagram of an electronic device according to another embodiment of the disclosure.

### DESCRIPTION OF THE EMBODIMENTS

Directional terms (e.g., up, down, right, left, front, back, top, bottom) as used herein are used for reference only to the drawings and are not intended to imply absolute orientation.

The disclosure is more fully described with reference to the drawings of the embodiment. However, the disclosure may be embodied in various different forms and should not be limited to the embodiments set forth herein only. The thickness, dimension, or size of layers or regions in the drawings may be exaggerated for clarity. The same or similar reference numerals denote the same or similar elements, and the descriptions are not repeated in the following paragraphs. In addition, descriptions of well-known components, methods, and materials may be omitted to avoid obscuring the description of the various principles of the disclosure.

It should be understood that, although the terms “first”, “second”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion.

Unless otherwise defined, all terms (including technical and scientific terms) used herein have the same meaning as that commonly understood by one of ordinary skill in the art to which this disclosure belongs.

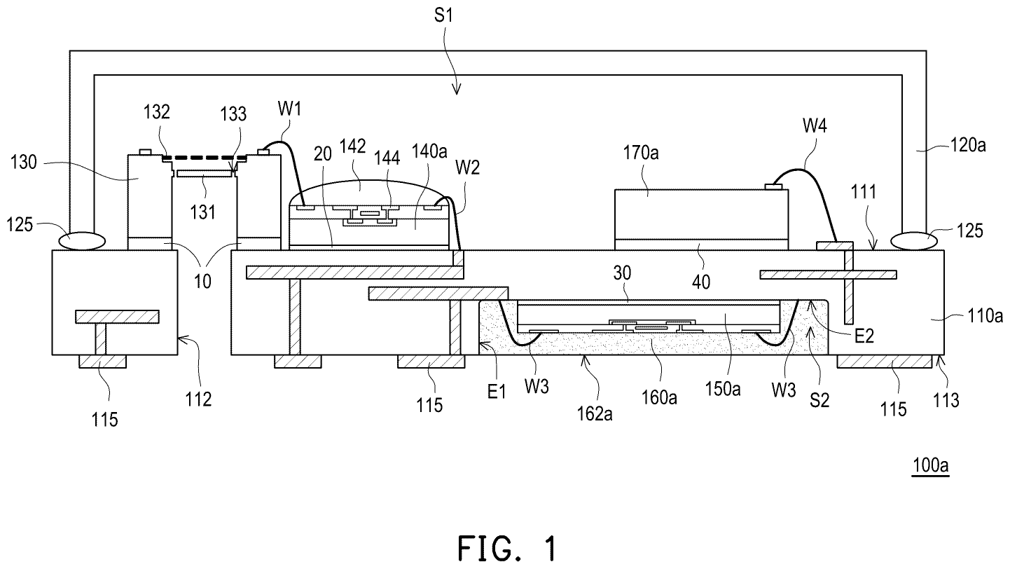

FIG. 1 is a schematic cross-sectional diagram of an electronic device according to an embodiment of the disclosure. Please refer to FIG. 1. In the embodiment, an electronic device 100a includes a first substrate 110a, a package 120a, a first sensing chip 130, a first processing chip 140a, a second processing chip 150a, and a first adhesive 160a. The first substrate 110a has a first surface 111 and a second surface 113 opposite to each other, and a via 112 penetrating through the first substrate 110a and connected to the first surface 111 and the second surface 113. The package 120a is disposed on the first surface 111 of the first substrate 110a and defines a first chamber S1 with the first substrate 110a. One of the first substrate 110a and the package 120a has a second chamber S2. The second chamber S2 has a first opening end E1 and a first bottom wall E2 opposite to each other. The first opening end E1 is facing a direction away from the first chamber S1. The first bottom wall E2 is located between the first opening end E1 and the first chamber S1. The first sensing chip 130 is disposed on the first surface 111 of the first substrate 110a, and is located in the first chamber S1 and covers the via 112. The first sensing chip 130 is electrically connected to the first processing chip 140a. The second processing chip 150a is disposed in the second chamber S2. The second processing chip 150a is air isolated from the first chamber S1. The first adhesive 160a is filled in the second chamber S2 and at least clads the second processing chip 150a.

In detail, in the embodiment, the first substrate 110a has the second chamber S2 extending from the second surface 113 toward the first surface 111. In one embodiment, the second chamber S2 is embodied as a recess. The first opening end E1 of the second chamber S2 is an entrance for components to enter and exit the chamber, which is not facing the first chamber S1 but is facing the direction away from the first chamber S1 (that is, outward). The first bottom wall E2 of the second chamber S2 is where components are placed. In one embodiment, the first substrate 110a may, for example, be a circuit substrate. For example, the first substrate 110a may, for example, be a printed circuit board (PCB). However, the disclosure is not limited thereto. The package 120a may be bonded to the first surface 111 of the first substrate 110a through a bonding member 125, and define the first chamber S1 with the first substrate 110a. In one embodiment, the package 120a may, for example, be a metal material, such as steel, brass, or copper, and may have electromagnetic shielding capability. However, the disclosure is not limited thereto. In one embodiment, the bonding member 125 may, for example, be a conductive metal material, such as solder ball, solder paste, or solder bump. However, the disclosure is not limited thereto.

In the embodiment, the first sensing chip 130 is disposed on the first surface 111 of the first substrate 110a through an adhesive layer 10 and covers the via 112. The first sensing chip 130 may include a diaphragm 131 and a vent hole 133 formed on the diaphragm 131. External air outside the via 112 may flow through the vent hole 133. In one embodiment, the first sensing chip 130 may further include a back plate 132 having multiple vias. The back plate 132 may be made of appropriate insulating materials, which is not limited herein. In one embodiment, the first sensing chip 130 may, for example, be a microphone element, to sense pressure changes generated by external sound wave vibrations. However, the disclosure is not limited thereto.

In the embodiment, the first processing chip 140a is, for example, disposed on the first surface 111 of the first substrate 110a through an adhesive layer 20, adjoining the first sensing chip 130, and located in the first chamber S1. The first sensing chip 130 is, for example, electrically connected to the first processing chip 140a through a bonding wire W1. The first processing chip 140a is, for example, electrically connected to the first substrate 110a through a bonding wire W2. In one embodiment, the first processing chip 140a may further include an insulation layer 142 and an internal circuit structure 144. The insulation layer 142 clads the bonding wires W1 and W2. The internal circuit structure 144 is electrically connected to the bonding wires W1 and W2. The insulation layer 142 and the internal circuit structure 144 may be any appropriate composition applied to the first processing chip 140a, which is not limited herein. In one embodiment, the first processing chip 140a may be an application specific integrated circuit (ASIC) to receive and process signals sensed by the first sensing chip 130.

In the embodiment, the second processing chip 150a is, for example, disposed in the second chamber S2 of the first substrate 110a through an adhesive layer 30. The second processing chip 150a is electrically connected to the first substrate 110a through a bonding wire W3. An active surface of the second processing chip 150a is facing downward. An active surface of the first processing chip 140a is facing upward. Here, the active surface refers to a surface of a semiconductor component provided with a conductive pad. Since the second processing chip 150a is located in the second chamber S2, and the second processing chip 150a is air isolated from the first chamber S1, the heat generated by the second processing chip 150a during operation may be isolated within the second chamber S2, which may avoid transmission to the first chamber S1 and affecting the operation of the first sensing chip 130, meaning that thermal interference between chips may be avoided. In addition, the first adhesive 160a filled in the second chamber S2 may form a stress buffer structure within the first substrate 110a in order to strengthen the overall rigidity of the first substrate 110a, which may avoid damage and/or warping of the first substrate 110a during high-temperature processes.

Moreover, in the embodiment, the first adhesive 160a completely fills, for example, the second chamber S2, cladding the second processing chip 150a and the bonding wire W3 in order to effectively protect the second processing chip 150a and the bonding wire W3, which may reduce the condition where the bonding wire W3 breaks when bonding with the first substrate 110a, and can increase structural reliability. In one embodiment, the first adhesive 160a has a top surface 162a away from the first bottom wall E2 of the second chamber S2. The top surface 162a is aligned with the second surface 113 of the first substrate 110a. In one embodiment, the top surface 162a of the first adhesive 160a is located between the first bottom wall E2 and the second surface 113, meaning that the first adhesive 160a does not protrude/is not beyond the second surface 113 of the first substrate 110a. In one embodiment, the second chamber S2 may be considered as an adhesive filled chamber. However, the disclosure is not limited thereto.

In addition, the electronic device 100a of the embodiment further includes a second sensing chip 170a, which is disposed on the first surface 111 of the first substrate 110a through an adhesive layer 40, and is located in the first chamber S1. The second sensing chip 170a may, for example, be electrically connected to the first substrate 110a through a bonding wire W4. The second sensing chip 170a may be electrically connected to the second processing chip 150a through the first substrate 110a. In one embodiment, the second sensing chip 170a is, for example, an environmental sensing element to sense air conditions from the external environment. For example, the second sensing chip 170a may be a barometer. However, the disclosure is not limited thereto. In one embodiment, when the second sensing chip 170a is a pressure sensing element, the second sensing chip 170a may have a component (not shown) similar to the diaphragm 131 of the first sensing chip 130 to obtain a needed physical quantity by the diaphragm deforming with pressure. In one embodiment, when the second sensing chip 170a is a temperature sensing element, the second sensing chip 170a may not have a component similar to the diaphragm 131 of the first sensing chip 130, so the specific design of the second sensing chip 170a may be determined according to the physical quantity intended to sense, which is not limited herein. In one embodiment, the second processing chip 150a may be an application specific integrated circuit (ASIC) to receive and process the signals sensed by the second sensing chip 170a.

In addition, the electronic device 100a of the embodiment may further include multiple conductive members 115, which are separately disposed on the second surface 113 of the first substrate 110a, and electrically connected to the first substrate 110a, the first processing chip 140a, and the second processing chip 150a. In one embodiment, the conductive members 115 may, for example, be electrodes. The material thereof may, for example, be solder paste. However, the disclosure is not limited thereto.

In brief, the package 120a and the substrate 110a of the embodiment define the first chamber S1. The first substrate 110a has the second chamber S2 extending from the second surface 113 toward the first surface 111. The first sensing chip 130 is located in the first chamber S1. The second processing chip 150a is located in the second chamber S2 and is air isolated from the first chamber S1. By means of this design, the first sensing chip 130 and the second processing chip 150a may be respectively disposed in different chambers, which can reduce interference generated by the second processing chip 150a on the first sensing chip 130 during operation, thereby allowing the electronic device 100a of the embodiment to have better sensing performance.

It must be noted here that the following embodiments use the element labels and a part of the content of the above-mentioned embodiment. Same or similar reference numerals are used to represent same or similar elements, and the description of the same technical content is omitted. The aforementioned embodiment may be referred to for the descriptions of the omitted parts, and descriptions of those parts will not be repeated in the following embodiments.

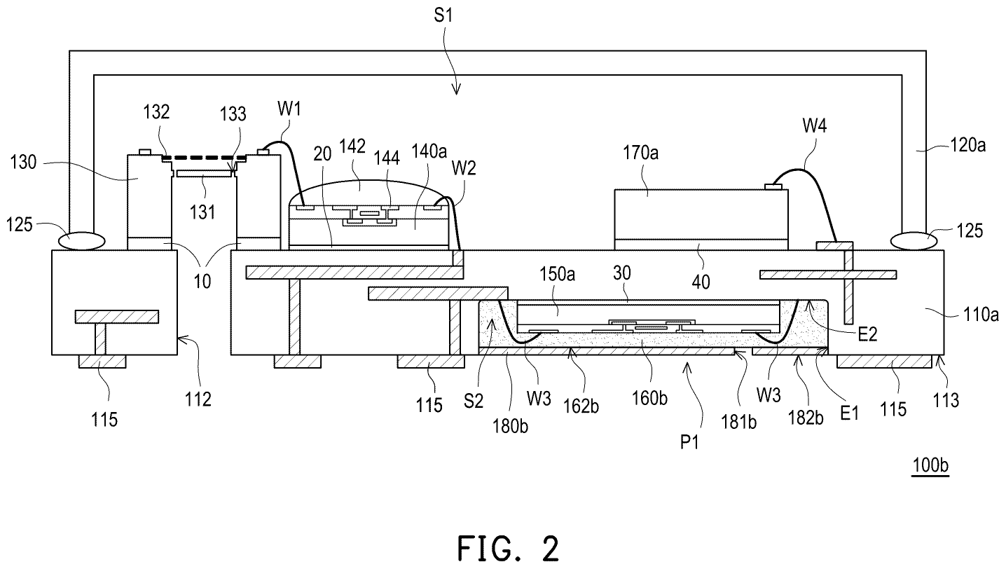

FIG. 2 is a schematic cross-sectional diagram of an electronic device according to another embodiment of the disclosure. Please refer to both FIG. 1 and FIG. 2 at the same time. An electronic device 100b of the embodiment is similar to the electronic device 100a. The main difference between both is that: in the embodiment, the electronic device 100b further includes a metal plate 180b, which is disposed on a top surface 162b of the first adhesive 160b, and covers the second chamber S2 and electrically connected to the first substrate 110a.

In detail, in the embodiment, the top surface 162b of the first adhesive 160b is located between the first bottom wall E2 of the second chamber S2 and the second surface 113 of the first substrate 110a, meaning that the top surface 162b of the first adhesive 160b is not beyond the second surface 113 of the first substrate 110a. In one embodiment, a surface 182b of the metal plate 180b that is relatively away from the top surface 162b of the first adhesive 160b is aligned with the second surface 113 of the first substrate 110a. In one embodiment, the surface 182b of the metal plate 180b is located between the top surface 162b of the first adhesive 160b and the second surface 113 of the first substrate 110a, meaning that the metal plate 180b is not beyond the second surface 113 of the first substrate 110a. In addition, to ensure pressure balance between the second chamber S2 and the outside, the metal plate 180b of the embodiment may have an opening 181b. The opening 181b exposes a portion of the top surface 162b of the first adhesive 160b. The metal plate 180b is grounded with the first substrate 110a. The metal plate 180b and the second chamber S2 of the first substrate 110a may define an electromagnetic protection chamber P1, that is, forming a Faraday cage, which may enhance the capability of the second processing chip 150a to resist interference.

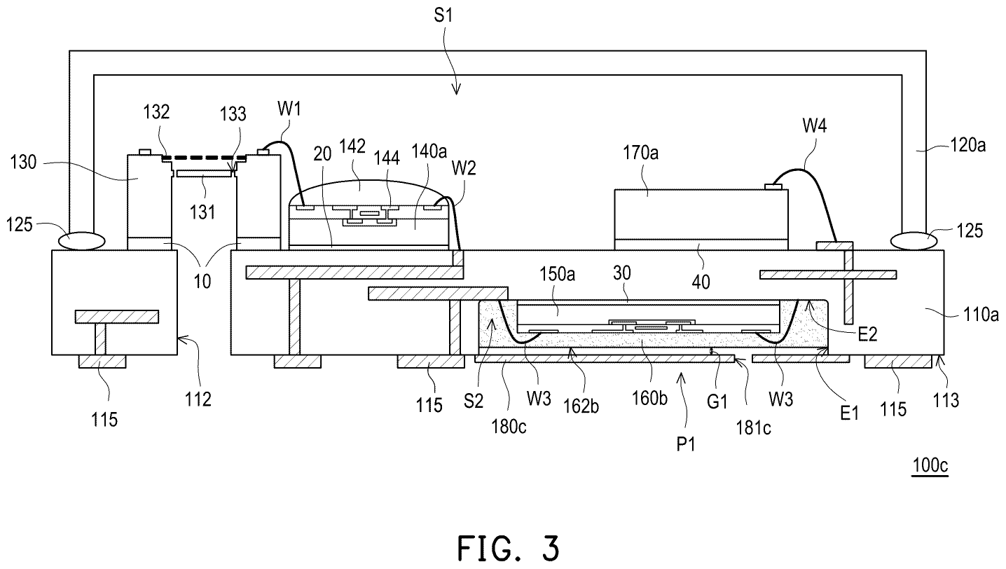

FIG. 3 is a schematic cross-sectional diagram of an electronic device according to another embodiment of the disclosure. Please refer to FIG. 2 and FIG. 3 at the same time. An electronic device 100c of the embodiment is similar to the electronic device 100b. The main difference between both is that: in the embodiment, a metal plate 180c is disposed on the top surface 162b of the first adhesive 160b and extends to cover the second surface 113 of the first substrate 110a. There is an air gap G1 between the metal plate 180c and the top surface 162b of the first adhesive 160b. In addition, to ensure pressure balance between the second chamber S2 and the outside, the metal plate 180c of the embodiment may have an opening 181c. The opening 181c exposes a portion of the top surface 162b of the first adhesive 160b.

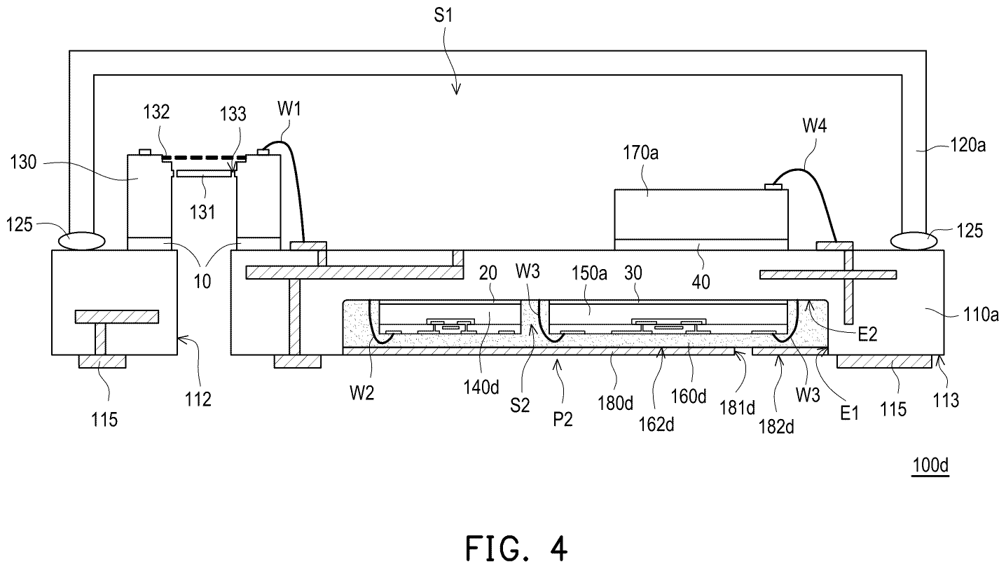

FIG. 4 is a schematic cross-sectional diagram of an electronic device according to another embodiment of the disclosure. Please refer to FIG. 1 and FIG. 4 at the same time. An electronic device 100d of the embodiment is similar to the electronic device 100a. The main difference between both is that: in the embodiment, a first processing chip 140d is disposed in the second chamber S2 of the first substrate 110a, adjoining the second processing chip 150a. The first processing chip 140d is, for example, electrically connected to the first substrate 110a through the bonding wire W2. In addition to cladding the second processing chip 150a and the bonding wire W3, a first adhesive 160d of the embodiment further clads the first processing chip 140d and the bonding wire W2 in order to effectively protect the first processing chip 140d, the second processing chip 150a, the bonding wire W2 and the bonding wire W3, which may reduce the condition where the bonding wire W2 and the bonding wire W3 break when bonding with the first substrate 110a, and can increase structural reliability.

In addition, the electronic device 100d of the embodiment further includes a metal plate 180d, which is disposed on a top surface 162d of the first adhesive 160d, and electrically connected to the first substrate 110a. In detail, in the embodiment, the top surface 162d of the first adhesive 160d is located between the first bottom wall E2 of the second chamber S2 and the second surface 113 of the first substrate 110a, meaning that the top surface 162d of the first adhesive 160d is not beyond the second surface 113 of the first substrate 110a. In one embodiment, a surface 182d of the metal plate 180d relatively away from the top surface 162d of the first adhesive 160d is aligned with the second surface 113 of the first substrate 110a. In one embodiment, the surface 182d of the metal plate 180d is located between the top surface 162d of the first adhesive 160d and the second surface 113 of the first substrate 110a, meaning that the metal plate 180d is not beyond the second surface 113 of the first substrate 110a. In one embodiment, the surface 182d of the metal plate 180d is aligned with the second surface 113 of the first substrate 110a. In addition, to ensure pressure balance between the second chamber S2 and the outside, the metal plate 180d of the embodiment may have an opening 181d. The opening 181d exposes a portion of the top surface 162d of the first adhesive 160d. The metal plate 180d is grounded with the first substrate 110a. The metal plate 180d and the second chamber S2 of the first substrate 110a may define an electromagnetic protection chamber P2, that is, forming a Faraday cage, which may enhance the capability of the first processing chip 140d and the second processing chip 150a to resist interference.

Since both the first processing chip 140d and the second processing chip 150a of the embodiment are disposed in the second chamber S2, and belong to different chambers from the first sensing chip 130 and the second sensing chip 170a disposed in the first chamber S1, the interference generated by the first processing chip 140d and the second processing chip 150a on the first sensing chip 130 and the second sensing chip 170a during operation may be effectively reduced, thereby allowing the electronic device 100d of the embodiment to have better sensing performance.

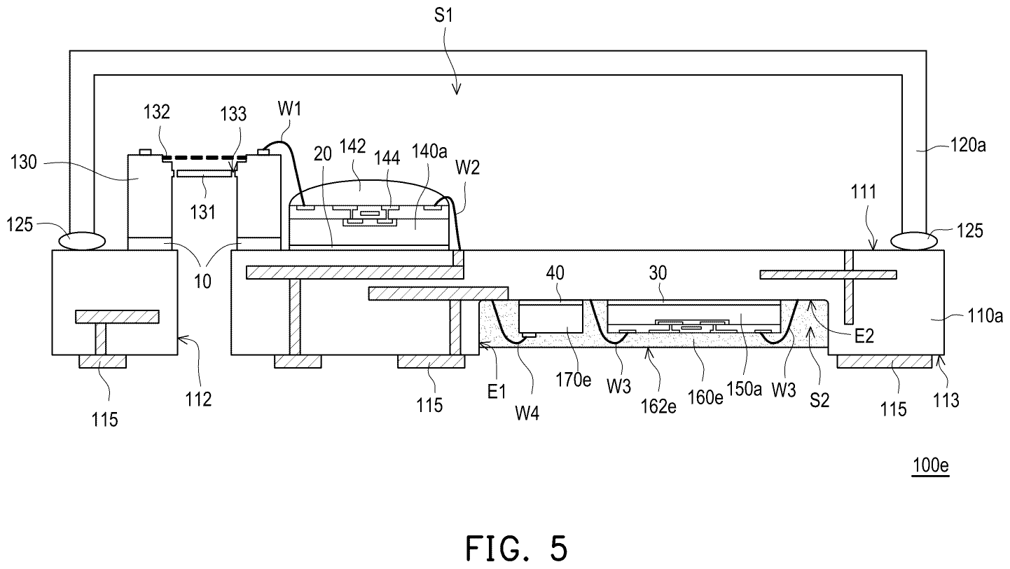

FIG. 5 is a schematic cross-sectional diagram of an electronic device according to another embodiment of the disclosure. Please refer to FIG. 1 and FIG. 5 at the same time. An electronic device 100e of the embodiment is similar to the electronic device 100a. The main difference between both is that: in the embodiment, a second sensing chip 170e is, for example, disposed in the second chamber S2 of the first substrate 110a through the adhesive layer 40, and adjoins the second processing chip 150a. The second sensing chip 170e may, for example, be electrically connected to the first substrate 110a through the bonding wire W4. The second sensing chip 170e may be electrically connected to the second processing chip 150a through the first substrate 110a. In addition to cladding the second processing chip 150a and the bonding wire W3, a first adhesive 160e of the embodiment further clads the second sensing chip 170e and the bonding wire W4 in order to effectively protect the second sensing chip 170e, the second processing chip 150a, the bonding wire W3, and the bonding wire W4, which may reduce the condition where the bonding wire W3 and the bonding wire W4 break when bonding with the first substrate 110a, and can increase structural reliability. Here, a top surface 162e of the first adhesive 160e is not beyond the second surface 113 of the first substrate 110a. However, the embodiment is not limited thereto.

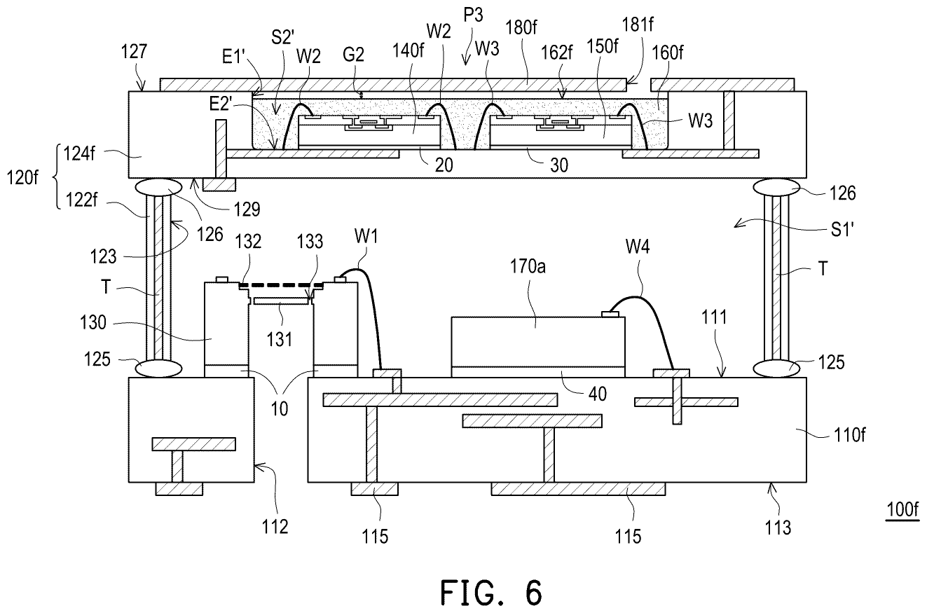

FIG. 6 is a schematic cross-sectional diagram of an electronic device according to another embodiment of the disclosure. Please refer to FIG. 1 and FIG. 6 at the same time. An electronic device 100f of the embodiment is similar to the electronic device 100a. The main difference between both is that: in the embodiment, the structure of a package 120f is different from the package 120a.

In detail, the package 120f of the embodiment includes a second substrate 122f and a third substrate 124f. The second substrate 122f is disposed on the first surface 111 of a first substrate 110f, and has an opening 123 through the second substrate 122f. The third substrate 124f is disposed on the second substrate 122f, and has a third surface 127 and a fourth surface 129 opposite to each other, and a second chamber S2′ extending from the third surface 127 toward the fourth surface 129. That is to say, the package 120f of the embodiment has the second chamber S2′. Furthermore, the second chamber S2′ has a first opening end E1′ and a first bottom wall E2′ opposite to each other. The first opening end E1′ is facing a direction away from the first chamber S1′. The first bottom wall E2′ is located between the first opening end E1′ and the first chamber S1′. Here, the first surface 111 of the first substrate 110f, the opening 123 of the second substrate 122f, and the fourth surface 129 of the third substrate 124f define a space of the first chamber S1′. The second substrate 122f may be bonded to the fourth surface 127 of the third substrate 124f through a bonding member 126. In one embodiment, the bonding member 126 may, for example, be a conductive metal material, such as solder ball, solder paste, or solder bump. However, the disclosure is not limited thereto. The second substrate 122f is electrically connected to the first substrate 110f and the third substrate 124f. In one embodiment, the second substrate 122f includes at least one conductive path (schematically shown as two conductive paths T). The first substrate 110f is electrically connected to the third substrate 124f by the conductive paths T of the second substrate 122f. In one embodiment, the second substrate 122f and the third substrate 124f may respectively be, for example, a circuit substrate, which may, for example, be a printed circuit board (PCB). However, the disclosure is not limited thereto.

Moreover, a first processing chip 140f of the embodiment is disposed in the second chamber S2′ of the third substrate 124f, adjoining a second processing chip 150f. In addition to cladding the second processing chip 150f and the bonding wire W3, a first adhesive 160f further clads the first processing chip 140f and the bonding wire W2 in order to effectively protect the first processing chip 140f, the second processing chip 150f, the bonding wire W2, and the bonding wire W3, which may reduce the condition where the bonding wire W2 and the bonding wire W3 break when bonding with the third substrate 124f, and can increase structural reliability. The first adhesive 160f has a top surface 162f away from the first bottom wall E2′ of the second chamber S2′. In one embodiment, the top surface 162f of the first adhesive 160f is located between the third surface 127 of the third substrate 124f and the first bottom wall E2′ of the second chamber S2′. In one embodiment, the top surface 162f of the first adhesive 160f is aligned with the third surface 127 of the third substrate 124f.

In addition, the electronic device 100f of the embodiment further includes a metal plate 180f, which is disposed above the top surface 162f of the first adhesive 160f, and extending to cover the second chamber S2′ and electrically connected to the third substrate 124f. The metal plate 180f extends to cover the third surface 127 of the third substrate 124f. That is to say, the metal plate 180f may be directly disposed on the third surface 127 of the third substrate 124f. Here, the metal plate 180f and the top surface 162f of the first adhesive 160f do not directly contact each other, and have an air gap G2. Moreover, to ensure pressure balance between the second chamber S2′ and the outside, the metal plate 180f of the embodiment has an opening 181f. The opening 181f exposes a portion of the top surface 162f of the first adhesive 160f. The metal plate 180f is grounded with the third substrate 124f. The metal plate 180f and the second chamber S2′ of the third substrate 124f may define an electromagnetic protection chamber P3, that is, forming a Faraday cage, which may enhance the capability of the first processing chip 140f and the second processing chip 150f to resist interference.

Since the first processing chip 140f and the second processing chip 150f of the embodiment are both disposed in the second chamber S2′, and belong to different chambers from the first sensing chip 130 and the second sensing chip 170a disposed in the first chamber S1′, the interference generated by the first processing chip 140f and the second processing chip 150f on the first sensing chip 130 and the second sensing chip 170a during operation may be effectively reduced, thereby allowing the electronic device 100f of the embodiment to have better sensing performance.

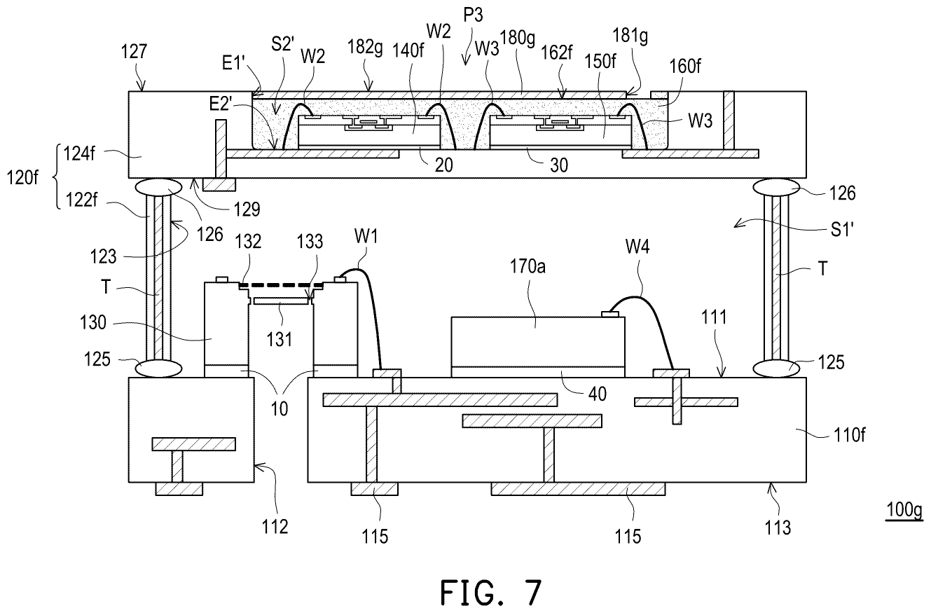

FIG. 7 is a schematic cross-sectional diagram of an electronic device according to another embodiment of the disclosure. Please refer to FIG. 6 and FIG. 7 at the same time. An electronic device 100g of the embodiment is similar to the electronic device 100f. The main difference between both is that: in the embodiment, a metal plate 180g is directly disposed on the top surface 162f of the first adhesive 160f. A surface 182g of the metal plate 180g relatively away from the top surface 162f of the first adhesive 160f is aligned with or is not beyond the third surface 127 of the third substrate 124f.

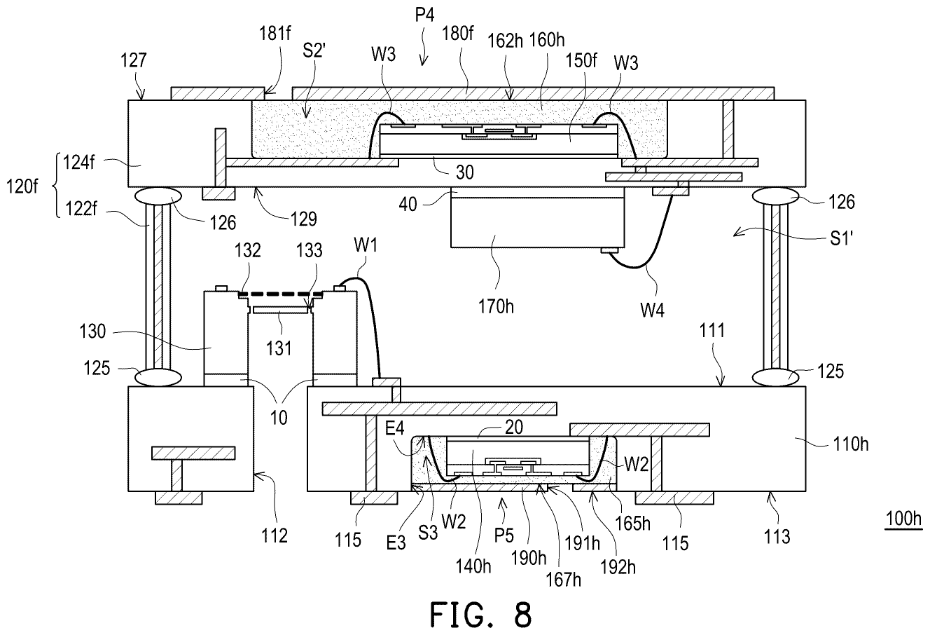

FIG. 8 is a schematic cross-sectional diagram of an electronic device according to another embodiment of the disclosure. Please refer to FIG. 6 and FIG. 8 at the same time. An electronic device 100h of the embodiment is similar to the electronic device 100f. The main difference between both is that: in the embodiment, a first substrate 110h further has a third chamber S3 extending from the second surface 113 toward the first surface 111. The third chamber S3 has a second opening end E3 and a second bottom wall E4 opposite to each other. The second opening end E3 is facing the direction away from the first chamber S1′. The second bottom wall E4 is located between the second opening end E3 and the first chamber S1′. A first processing chip 140h is disposed in the third chamber S3 of the first substrate 110h. At this time, the first chamber S1′ is located between the second chamber S2′ and the third chamber S3. A second sensing chip 170h is disposed on the fourth surface 129 of the third substrate 124f, and is located in the first chamber S1′. The second sensing chip 170h is electrically connected to the second processing chip 150f through the third substrate 124f. That is to say, a first adhesive 160h only clads the second processing chip 150f and the bonding wire W3. A top surface 162h of the first adhesive 160h is aligned with the third surface 127 of the third substrate 124f. The metal plate 180f directly contacts the top surface 162h of the first adhesive 160h and extends to the third surface 127 of the third substrate 124f.

Moreover, the electronic device 100h of the embodiment further includes a second adhesive 165h, which is filled in the third chamber S3 of the first substrate 110h, and at least clads the first processing chip 140h. Specifically, the second adhesive 165h clads the first processing chip 140h and the bonding wire W2 in order to effectively protect the first processing chip 140h and the bonding wire W2, which may reduce the condition where the bonding wire W2 breaks when bonding with the first substrate 110h, and can increase structural reliability. The second adhesive 165h has a top surface 167h away from the second bottom wall E4 of the third chamber S3. In one embodiment, the top surface 167h of the second adhesive 165h is located between the second bottom wall E4 and the second surface 113 of the third chamber S3, meaning that the top surface 167h of the second adhesive 165h is not beyond the second surface 113 of the first substrate 110h. In addition, the electronic device 100h of the embodiment further includes a metal plate 190h, which is disposed on the top surface 167h of the second adhesive 165h. To ensure pressure balance between the third chamber S3 and the outside, the metal plate 190h of the embodiment has an opening 191h. The opening 191h exposes a portion of the top surface 167h of the second adhesive 165h. In one embodiment, a surface 192h of the metal plate 190h relatively away from the top surface 167h of the second adhesive 165h is aligned with the second surface 113 of the first substrate 110h. The metal plate 190h is grounded with the first substrate 110h. The metal plate 190h and the third chamber S3 of the first substrate 110h may define an electromagnetic protection chamber P5, that is, forming a Faraday cage, which may enhance the capability of the first processing chip 140h to resist interference.

Since the first processing chip 140h and the second processing chip 150f of the embodiment are respectively disposed in the third chamber S3 and the second chamber S2′, and belong to different chambers from the first sensing chip 130 and the second sensing chip 170h disposed in the first chamber S1′, the interference generated by the first processing chip 140h and the second processing chip 150f on the first sensing chip 130 and the second sensing chip 170h during operation may be effectively reduced, thereby allowing the electronic device 100h of the embodiment to have better sensing performance.

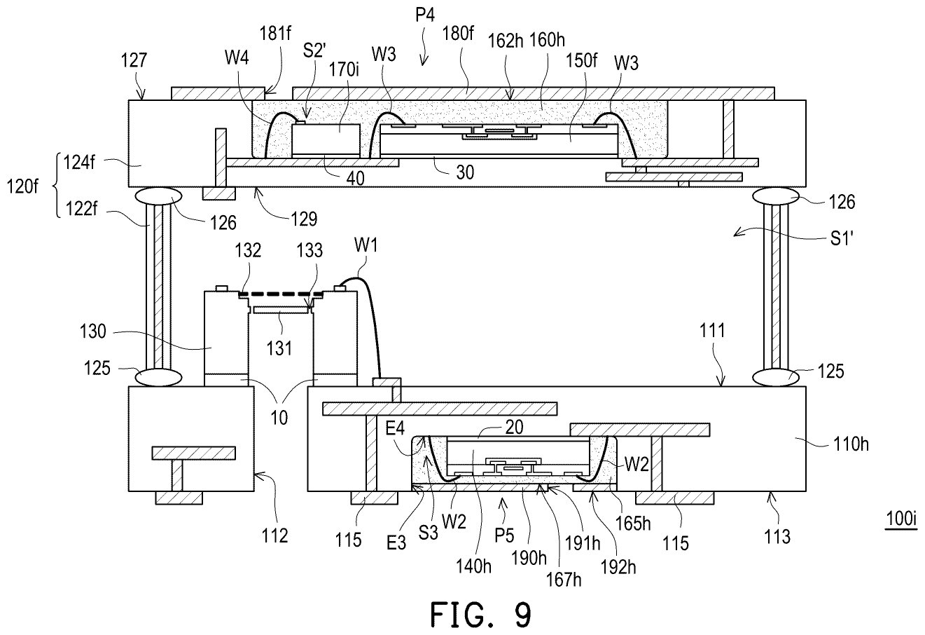

FIG. 9 is a schematic cross-sectional diagram of an electronic device according to another embodiment of the disclosure. Please refer to FIG. 8 and FIG. 9 at the same time. An electronic device 100i of the embodiment is similar to the electronic device 100h. The main difference between both is that: in the embodiment, a second sensing chip 170i is, for example, disposed in the second chamber S2′ of the third substrate 124f through the adhesive layer 40, and adjoins the second processing chip 150f. The second sensing chip 170i may, for example, be electrically connected to the third substrate 124f through the bonding wire W4. The second sensing chip 170i may be electrically connected to the second processing chip 150f through the third substrate 124f. In addition to cladding the second processing chip 150f and the bonding wire W3, the first adhesive 160h of the embodiment further clads the second sensing chip 170i and the bonding wire W4 in order to effectively protect the second sensing chip 170i, the second processing chip 150f, the bonding wire W3 and the bonding wire W4, which may reduce the condition where the bonding wire W3 and the bonding wire W4 break when bonding with the third substrate 124f, and can increase structural reliability.

In summary, in the design of the electronic device of the disclosure, the package and the substrate define a first chamber. One of the first substrate and the package has a second chamber. The first sensing chip is located in the first chamber. The second processing chip is located in the second chamber and is air isolated from the first chamber. By means of this design, the sensing chip and the processing chip may be respectively disposed in different chambers, which can reduce the interference generated by the processing chip on the sensing chip during operation, thereby allowing the electronic device of the disclosure to have better sensing performance.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. An electronic device, comprising:
a first substrate, having a first surface and a second surface opposite to each other, a via penetrating through the first substrate and connected to the first surface and the second surface;
a package, disposed on the first surface of the first substrate, and defining a first chamber with the first substrate, wherein one of the first substrate and the package has a second chamber, the second chamber has a first opening end and a first bottom wall opposite to each other, the first opening end is facing a direction away from the first chamber, and the first bottom wall is located between the first opening end and the first chamber;
a first sensing chip, disposed on the first surface of the first substrate, and located in the first chamber and covering the via, wherein the first sensing chip is electrically connected to a first processing chip;
a second processing chip, disposed in the second chamber, wherein the second processing chip is air isolated from the first chamber; and
a first adhesive, filled in the second chamber, and at least cladding the second processing chip.

2. The electronic device according to claim 1, wherein the first substrate has the second chamber extending from the second surface toward the first surface.

3. The electronic device according to claim 2, wherein the first processing chip is disposed in the second chamber of the first substrate, adjoining the second processing chip, and the first adhesive further clads the first processing chip.

4. The electronic device according to claim 2, wherein the first adhesive has a top surface away from the first bottom wall of the second chamber, and the top surface is aligned with or is not beyond the second surface of the first substrate.

5. The electronic device according to claim 2, further comprising:
a metal plate, disposed on the top surface of the first adhesive, and covering the second chamber and electrically connected to the first substrate, wherein the metal plate has an opening, and the opening exposes a portion of the top surface of the first adhesive.

6. The electronic device according to claim 5, wherein the metal plate extends to cover the second surface of the first substrate, and there is an air gap between the metal plate and the first adhesive.

7. The electronic device according to claim 5, wherein a surface of the metal plate relatively away from the top surface of the first adhesive is aligned with or is not beyond the second surface of the first substrate.

8. The electronic device according to claim 2, further comprising:
a second sensing chip, disposed in the second chamber of the first substrate, adjoining the second processing chip, and the first adhesive further cladding the second sensing chip.

9. The electronic device according to claim 1, further comprising:
a second sensing chip, disposed on the first surface of the first substrate, and located in the first chamber, wherein the second sensing chip is electrically connected to the second processing chip through the first substrate.

10. The electronic device according to claim 1, wherein the package comprises:
a second substrate, disposed on the first surface of the first substrate, and having an opening penetrating through the second substrate; and
a third substrate, disposed on the second substrate, and having a third surface and a fourth surface opposite to each other and a second chamber extending from the third surface toward the fourth surface, wherein the first surface of the first substrate, the opening of the second substrate and the fourth surface of the third substrate define a space of the first chamber, and the second substrate comprises at least one conductive path, and the first substrate is electrically connected to the third substrate by the at least one conductive path of the second substrate.

11. The electronic device according to claim 10, wherein the first processing chip is disposed in the second chamber of the third substrate, adjoining the second processing chip, and the first adhesive further clads the first processing chip.

12. The electronic device according to claim 10, wherein the first adhesive has a top surface away from the first bottom wall of the second chamber, and the top surface is aligned with or is not beyond the third surface of the third substrate.

13. The electronic device according to claim 10, further comprising:
a metal plate, disposed on the top surface of the first adhesive, and extending to cover the second chamber and electrically connected to the third substrate, wherein the metal plate has an opening, and the opening exposes a portion of the top surface of the first adhesive.

14. The electronic device according to claim 13, wherein the metal plate extends to cover the third surface of the third substrate, and there is an air gap between the metal plate and the first adhesive.

15. The electronic device according to claim 10, wherein the first substrate has a third chamber extending from the second surface toward the first surface, the third chamber has a second opening end and a second bottom wall opposite to each other, the second opening end is facing the direction away from the first chamber, and the second bottom wall is located between the second opening end and the first chamber, and the first processing chip is disposed in the third chamber of the first substrate.

16. The electronic device according to claim 15, further comprising:
a second sensing chip, disposed on the fourth surface of the third substrate, and located in the first chamber, wherein the second sensing chip is electrically connected to the second processing chip through the third substrate.

17. The electronic device according to claim 15, further comprising:
a second sensing chip, disposed in the second chamber of the third substrate, adjoining the second processing chip, and the first adhesive further cladding the second sensing chip.

18. The electronic device according to claim 15, further comprising:
a second adhesive, filled in the third chamber of the first substrate, and at least cladding the first processing chip.

19. The electronic device according to claim 18, further comprising:
a metal plate, disposed on the top surface of the second adhesive, and electrically connected to the first substrate, wherein the metal plate has an opening, and the opening exposes a portion of the top surface of the second adhesive.

20. The electronic device according to claim 1, further comprising:
a plurality of conductive members, disposed on the second surface of the first substrate, and electrically connected to the first processing chip and the second processing chip.
